(19) United States
(12) Patent Application Publication
(10) Pub. No.: US 2026/0182398 A1
(43) Pub. Date: Jun. 25, 2026

(54) PACKAGE STRUCTURES AND MANUFACTURING METHOD OF THE SAME

(71) Applicant: Taiwan Semiconductor Manufacturing Company, Ltd., Hsinchu (TW)

(72) Inventors: Po-Ching Wu, Hsinchu (TW); Meng-Tsan Lee, Hsinchu (TW); Li-Han Hsu, Hsin-Chu City (TW); An-Jhih Su, Taoyuan City (TW)

(73) Assignee: Taiwan Semiconductor Manufacturing Company, Ltd., Hsinchu (TW)

(21) Appl. No.: 18/988,820

(22) Filed: Dec. 19, 2024

(51) Int. Cl. H01L 23/538; H01L 23/00; H01L 23/13; H01L 23/15; H01L 23/48; H01L 25/00; H01L 25/11

(52) U.S. Cl. CPC H10W 70/611; H10W 70/68; H10W 90/00; H10W 90/401; H10W 20/20; H10W 70/692; H10W 90/22; H10W 90/701

(57) ABSTRACT

A package structure and manufacturing methods thereof are described. The package structure includes a substrate, an intermediary structure, a first semiconductor structure and a second semiconductor structure. The substrate includes a package substrate unit and an insulating material covering sidewalls of the package substate unit. The intermediary structure is disposed on the substrate. The intermediary structure includes conductive pillars and an encapsulating material laterally wrapping the conductive pillars. The first semiconductor structure is disposed on the substrate and embedded in the encapsulating material. The second semiconductor structure is disposed over the intermediary structure and electrically connected with the first semiconductor structure through the intermediary structure.

### BACKGROUND

In the field of semiconductor packaging, it is important to satisfying the demand for miniaturization and integration of multiple semiconductor components, subunits and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 though FIG. 7 are schematic cross-sectional and top views illustrating structures produced at various stages of a method of forming a package structure in accordance with some embodiments of the present disclosure.

FIG. 8 is a schematic cross-sectional view of an exemplary structure of a package structure in accordance with an embodiment of the present disclosure.

FIGS. 9-13 are schematic cross-sectional views of exemplary package structures in accordance with some embodiments of the present disclosure.

### DETAILED DESCRIPTION

The present disclosure relates generally to packaging devices and methods of manufacturing, for semiconductor devices.

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In some embodiments, the manufacturing method is part of a package manufacturing process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. Throughout the various views and illustrative embodiments, like reference numbers are used to designate like elements.

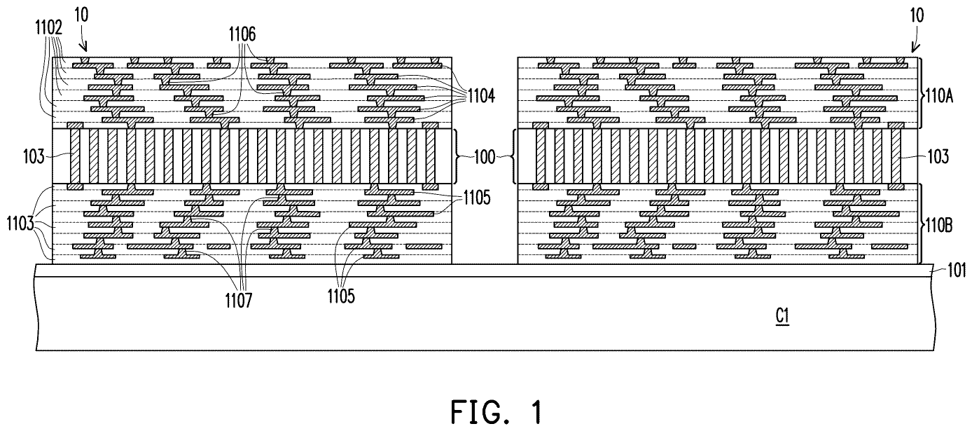

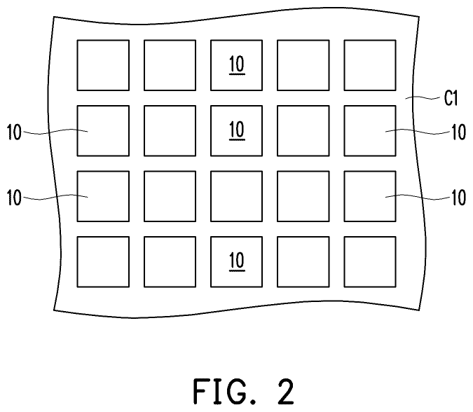

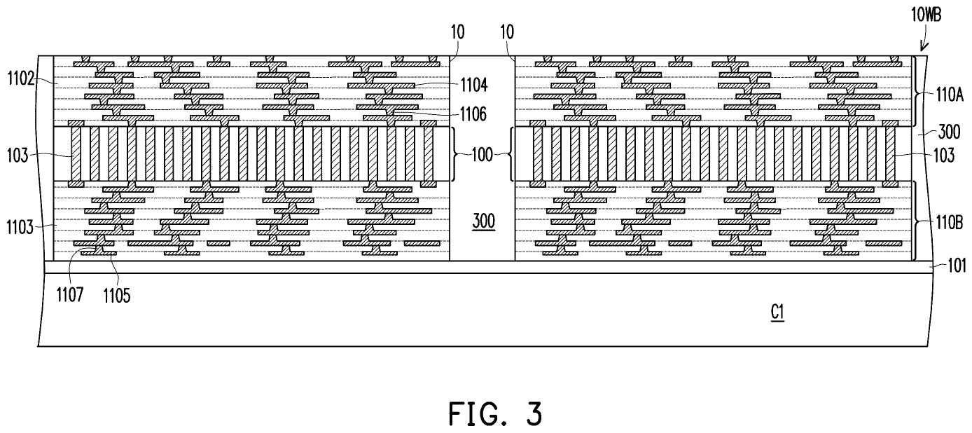

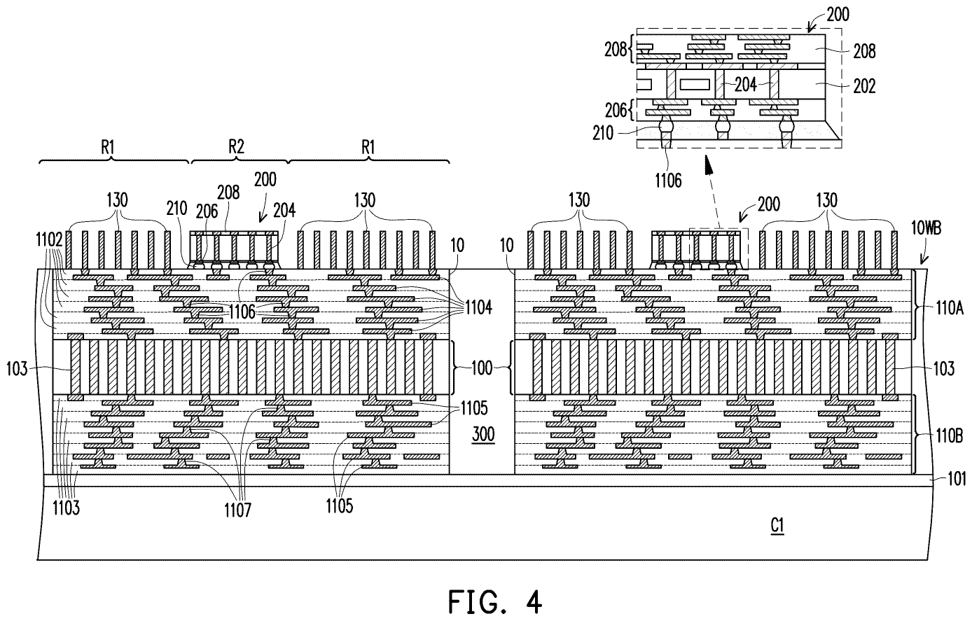

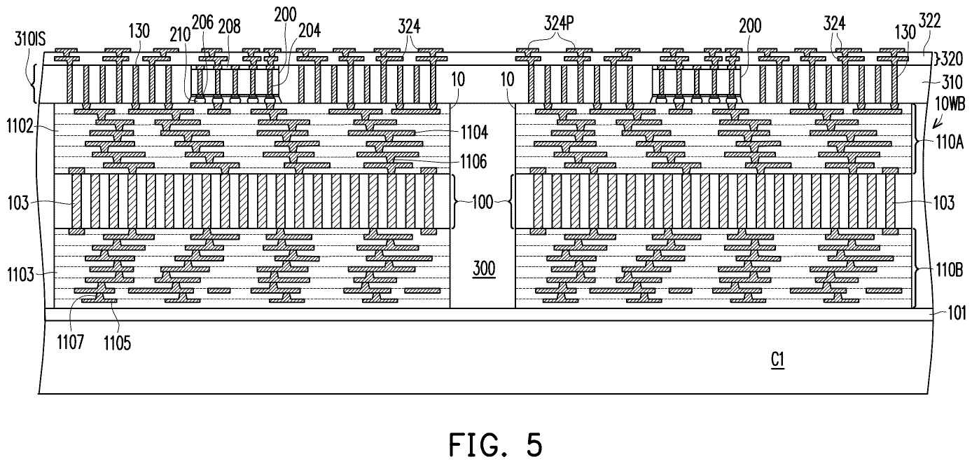

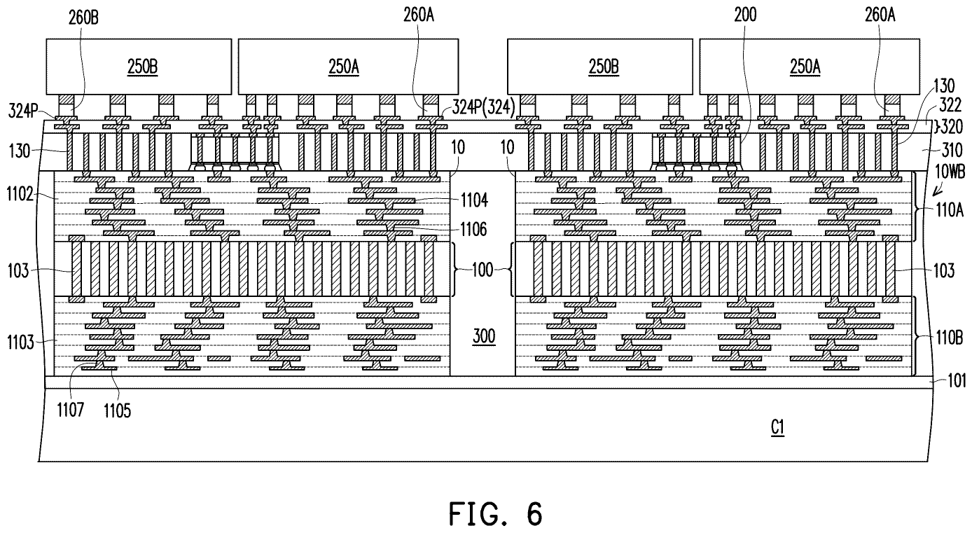

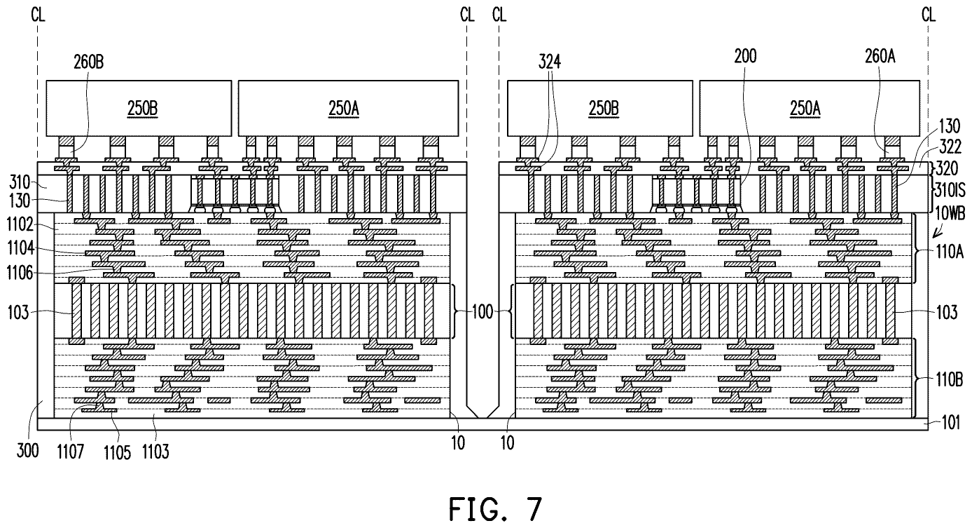

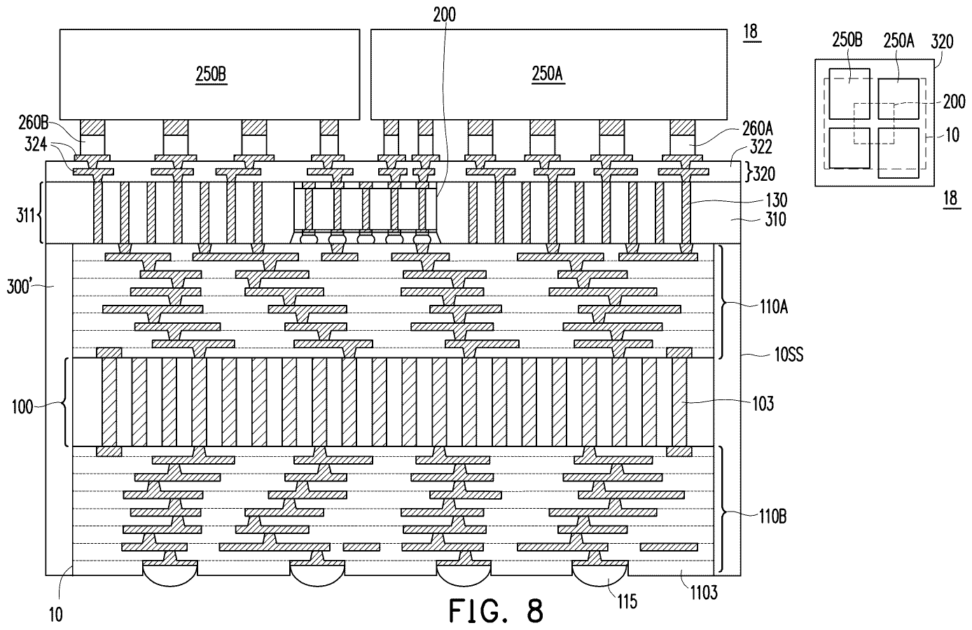

FIG. 1 though FIG. 7 are schematic cross-sectional and top views illustrating structures produced at various stages of a method of forming a package structure in accordance with some embodiments of the present disclosure. FIG. 8 is a schematic cross-sectional view of an exemplary structure of a package structure in accordance with an embodiment of the present disclosure. The exemplary structure shown in FIG. 8 may be obtained following the process steps as depicted from FIG. 1 through FIG. 7.

Referring to FIG. 1 and FIG. 2, in some embodiments, multiple package substrate units 10 are provided and disposed on a carrier C1. As seen in the schematic top view of FIG. 2, the package substrate units 10 are arranged side by side but spaced apart from one another with gaps there-between, and the package substrate units 10 may be arranged as an array on the carrier C1. In some embodiments, the package substrate units 10 are known good substrate units, and are obtained through prefabricating one or more circuit substrates or package substrates in a panel level, dicing the circuit/package substrate into package substrate units, and individually testing for connection and reliability, so that only known good package substrate units are used and assembled. In some embodiments, more and different types of package substrate units may be provided and reconstructed into a board or panel like structure.

In some embodiments, the package substrate unit 10 includes a core layer 100 having multiple through core vias 103 and film stacks 110A and 110B stacked upon two opposite sides of the core layer 100 and covering both sides of the core layer 100. In some embodiment, the package substrate unit 10 may be adhered (attached) onto the carrier C1 through a temporary bonding layer 101 formed on the carrier C1. In some embodiments, the temporary bonding layer 101 may also include a release layer for facilitating the removal of the carrier C1 in the subsequent process steps. The carrier C1 may include a glass plate, a metal plate, a plastic supporting board or the like, or any other suitable supportive materials may be used as long as the materials are able to withstand the subsequent steps of the process.

According to some embodiments, the core layer 100 of the package substrate unit 10 includes a glass layer, and the glass may be an amorphous solid. In some embodiments, the core layer 100 may be formed from a material selected from alkali glass, non-alkali glass, fused silica, pure silica, soda-lime glass, borosilicate glass, and aluminosilicate glass; however, the disclosure is not specifically limited thereto. It should be noted that glasses having alternative base materials (for example, fluoride glasses, phosphate glasses, chalcogen glasses, etc.) may also be employed. Further, any combination of other materials and additives may be combined with silica (or other base material) to form a glass having desired physical properties. Examples of these additives may further include magnesium, calcium, manganese, aluminum, lead, boron, iron, chromium, potassium, sulfur, and antimony, carbonates and/or oxides and other elements. The aforementioned glasses and additives are but a few examples of the many types of materials and material combinations that may be used for fabricating the core layer 100 of the present disclosure. In addition, when the core layer 100 is a glass layer, surface treatments and/or coatings may be included to improve strength and/or durability, and the glass core layer may be annealed to reduce internal stresses. In some embodiment, the glass material used for the core layer 100 does not include organic polymer materials. In certain embodiments, the core layer 100 includes a single piece of glass. In other embodiments, the core layer 100 includes two or more glass sheets or multiple sections of glass joined together. The core layer 100 may be rigid enough to support the package substrate and to counterbalance the warpage of the package.

Referring to FIG. 1, the film stacks 110A and 110B are formed respectively on opposing sides of the package substrate unit 10, and the film stacks 110A and 110B are electrically connected through the through core vias (TCVs) 103 so that the package substrate unit 10 provides double sided electrical connectivity. In an embodiment, as long as the TCVs 103 electrically connect the film stacks 110A and 110B disposed on opposing sides of the package substrate unit 10 with each other, the TCVs 103 may be or include metallic through vias, plated through hole structures or filled plated through hole structures. In some embodiments, as seen in FIG. 1, the TCVs 103 in the core layer 100 extend through the core layer 100 and connect with the metal wiring layers of the film stacks 110A, 110B. For example, the formation of the TCVs 103 involves forming through holes in the core layer 100 by imprinting, casting, laser drilling, etching, or any other suitable techniques, and then forming a metal or conductive metallic material filling into the through holes to form the TCVs 103. In some embodiments, the metallic material of the TCVs 103 includes metals, for example copper, tin, silver, gold, nickel, aluminum, and tungsten, as well as alloys of these metals. In one embodiment, the core layer 100 includes a glass layer and the TCVs 103 are through glass vias. In some embodiments, critical dimensions of the TCVs 103 may ranges from about 5 μm to about 300 μm, or from about 50 μm to about 150 μm, and the average pitch among the TCVs 103 may be in the range of about 10 μm to about 600 μm or 100 μm to about 300 μm. In some embodiments, the aspect ratio of the TCVs 103 may be in the range of 2˜100 or 3˜15. However, the disclosure is not limited thereto.

Specifically, referring to FIG. 1, the film stack 110A includes a stack of insulating sublayers 1102, metal wiring layers 1104 and vias 1106 and the film stack 110B includes a stack of insulating sublayers 1103, metal wiring layers 1105 and vias 1107. For example, the metal wiring layers 1104 or 1105 may include metal routing lines, pads or contacts, and the metal wiring layer(s) 1104, 1105 and the via(s) 1106, 1107 that are embedded in the corresponding insulating sublayer(s) 1102, 1103 are electrically interconnected to provide electrical connection for the film stacks 110A and 110B. For example, the topmost vias 1106 of the film stack 110A may be exposed for further connection. In some embodiments, the insulating sublayer(s) 1102, 1103 may be any suitable materials, including polymeric materials, ceramic materials, plastics, composite materials, liquid crystal polymers (LCPs), epoxy laminates of fiberglass sheets, Prepreg, and resins including Ajinomoto build-up film (ABF), or combinations thereof. In one embodiment, the bottommost insulating sublayer 1103 of the film stack 110B may be or include a solder resist layer. In some embodiments, the insulating sublayer(s) 1102, 1103 may be formed by coating, deposition, lamination, or any other suitable technique. In some embodiments, the insulating sublayer(s) 1102, 1103 are build-up sublayers. In some embodiments, the material of the metal wiring layer(s) 1104, 1105 may include copper, aluminum, silver, or the like, and the metal wiring layer(s) 1104, 1105 may be formed by plating processes, including electroplating, or electroless plating. In some embodiments, the metal wiring layer(s) 1104, 1105 formed in the film stacks 110A and 110B may be formed with patterns and configuration to facilitate routing of power and transmission of input/output (I/O) signals, and to route signals and power through the semiconductor package. It should be noted that the numbers of the through vias, sublayers, patterns are merely exemplary from the perspective of the manufacturing process and not intended to limit the scope of this disclosure. For example, the film stacks 110A and 110B may constitute more or less sublayers, and the number and thickness of each insulating sublayer may be adjusted according to design requirement. In FIG. 1, the first and the second film stacks 110A and 110B are shown to have the same number of insulating sublayers. In some alternative embodiments, the number of insulating sublayers on either side of the package substrate unit 10 may be different.

Referring to FIG. 3, an insulating filling material 300 is disposed over the carrier C1, covering the package substrate units 10 and filling up the gaps and spaces between the package substrate units 10 and a reconstructed package substrate board 10WB is formed. In some embodiment, the gaps between the package substrate units 10 are filled by the insulating filling material 300 and the sidewalls of the package substrate units 10 are covered by the insulating filling material 300. In some embodiments, the insulating filling material 300 fully covers the package substrate units 10 (covering top surfaces and sidewalls of the package substrate units 10) and fills up the gaps between the package substrate units 10, and later a planarization process is performed to remove a portion of the insulating filling material 300 to reveal the film stack 110A from the insulating filling material 300. In some embodiments, the planarization process includes chemical mechanical polishing (CMP), and optionally an etching process may be performed.

For example, the reconstructed package substrate board 10WB is in a form of a board, a plate or a panel, and may include a plurality of units (only two are shown in FIG. 7), and it is understood that each unit obtained after the singulation may include one or more known good package substrate units of the same type or of different types. The shape of the reconstructed package substrate board 10WB is not particularly limited and may be rectangular, square, oval, round or polygonal shapes.

In some embodiments, the insulating filling material 300 may be formed of any suitable insulating material, including polymeric materials such as epoxy resins, phenolic resins or silicon containing resins, plastics, composite materials, or combination thereof. In one embodiment, the material of the insulating filling material 300 includes epoxy resin with fillers, and the fillers may include silica fillers, aluminum oxide fillers, silicon nitride fillers aluminum nitride fillers, boron nitride fillers or carbon-series fillers, with a ratio of the resin to the fillers ranging from about 1:1 to about 1:30. The formation method of the insulating filling material 300 may include molding, coating, dispensing, deposition, lamination or combinations thereof, and a curing process may also be applied. In some embodiments, the material of the insulating filling material 300 is chosen to have a minimal coefficient of thermal expansion (CTE) mismatch with the package substate units 10.

Referring to FIG. 4, in some embodiments, a plurality of conductive pillars 130 is formed on the exposed film stack 110A of the package substrate units 10 within the reconstructed package substrate board 10WB and bonded to the topmost vias 1106 of the exposed film stack 110A of the package substrate units 10. In some embodiments, multiple first semiconductor dies 200 are mounted on the exposed film stack 110A of the package substrate units 10 within the reconstructed package substrate board 10WB and bonded to the topmost vias 1106 of the exposed film stack 110A of the package substrate units 10. In some embodiments, the conductive pillars 130 are formed on the conductive vias 1106 in the non-die-placement region R1, instead of the die-placement region R2 of the package substrate unit 10. In some embodiments, the conductive pillars 130 are metallic pillars.

In some embodiments, the conductive pillars 130 are preformed and bonded to the topmost vias 1106 in the non-die-placement region R1, surrounding the die-placement region R2. For example, pre-fabricated copper pillars may be picked-and-placed and bonded to the vias 1106 by performing a bonding process. For example, the conductive pillars 130 are formed from a metal material and/or metal alloys, including copper, nickel, titanium, alloys thereof, or combinations thereof, and the formation of the conductive pillars 130 may include plating such as an electroplating process. In some embodiments, the conductive pillars 130 are formed directly on the conductive vias 1106 though plating with a mask pattern (not shown). In some embodiments, the formation of the conductive pillars 130 involves forming a seed material layer (such as titanium/copper composite layer), forming the mask pattern with openings, forming copper pillars through a plating process, and removing the mask pattern. The locations for the conductive pillars 130 are limited within the footprints of the package substrate units 10 and mainly in the non-die-placement region R1 beside the die-placement region R2. That is, there is no conductive pillar 130 located on the insulating filling material 300.

In some embodiments, critical dimensions of the conductive pillars 130 may ranges from about 5 μm to about 300 μm, or from about 40 μm to about 200 μm, and the average pitch among the conductive pillars 130 may be in the range of about 10 μm to about 600 μm or 80 μm to about 300 μm. In some embodiments, the aspect ratio of the conductive pillars 130 may be in the range of 1˜100 or 2˜5. However, the disclosure is not limited thereto.

A schematic enlarged cross-sectional view of a portion of the first semiconductor die 200 is shown at the upper part of the FIG. 4. In some embodiments, the first semiconductor die 200 includes a semiconductor substrate 202 having a plurality of through substrate vias (TSVs) 204 penetrating there-through, the connecting structures 206, 208 disposed on two opposite side of the semiconductor substrate 202, and connectors 210 disposed at connecting structure 206. In some embodiments, the connectors 210 and the connecting structures 206, 208 are electrically connected with the TSVs 204 so as to establish electrical paths for both sides and provide double-sided electrical connectivity. In some embodiments, the first semiconductor dies 200 are bonded to the topmost vias 1106 of the package substrate units 10 through the connectors 210 so that the first semiconductor dies 200 are electrically connected with the package substrate units 10 within the reconstructed package substrate board 10WB. In some embodiments, the connectors 210 are or include micro-bumps, or metal posts with solder paste.

Through the TSVs 204 formed inside the first semiconductor dies 200, the first semiconductor dies 200 are capable of establishing electrical connection paths for components or dies from either or both of the upper and lower sides, or electrically connecting components or elements located at the upper and lower sides, thus providing double-sided electrical connection (connectivity).

In some embodiments, the first semiconductor dies 200 may be device dies including devices such as voltage regulators, transmitters, receivers, amplifiers, capacitors, inductors, power management integrated circuits (PMIC), or switches, combinations thereof. In some embodiments, the first semiconductor dies 200 may be an integrated passive device (IPD) die. In some embodiments, the first semiconductor dies 200 may function as a bridge die for interconnecting other adjacent semiconductor dies.

Referring to FIG. 5, an insulating layer 310 is formed on and over the reconstructed package substrate board 10WB, covering the conductive pillars 130 and the first semiconductor dies 200 and covering the exposed film stacks 110A of the package substrate units 10 and the insulating filling material 300 sandwiched between the package substrate units 10.

In some embodiment, the gaps between the conductive pillars 130 and between the conductive pillars 130 and the first semiconductor dies 200 on the package substrate units 10 are filled by the insulating layer 310 and the sidewalls of the first semiconductor dies 200 on the package substrate units 10 are covered by the insulating layer 310. In some embodiments, the insulating layer 310 is formed with a larger height (thickness) and fully covers top surfaces and sidewalls of the conductive pillars 130 and the first semiconductor dies 200, and later a planarization process is performed to remove a portion of the insulating layer 310 to reveal the tops of the conductive pillars 130 and reveal the top sides (i.e. the top surfaces of the connecting structures 208) of the first semiconductor dies 200 from the insulating layer 310. In some embodiments, the planarization process includes chemical mechanical polishing (CMP), and optionally an etching process may be performed. In one embodiment, the tops of the conductive pillars 130, the top sides of the first semiconductor dies 200 and the top surface of the insulating layer 310 are substantially levelled so as to provide an even plane for the later formed redistribution structure. In FIG. 5, the conductive pillars 130 extending through the insulating layer 310 (extending from the top surface to the bottom surface of the planarized insulating layer 310) are through insulation vias. The structure of the conductive pillars 130 laterally encapsulated by the insulating layer 310 may be considered as a large-scale constructed interposer 310IS located over the reconstructed package substrate board 10WB. The constructed interposer 310IS and the reconstructed package substrate board 10WB may function as a large-scale reformed substrate structure. In some embodiments, at least one first semiconductor die 200 is included in the constructed interposer 310IS.

In some embodiments, the insulating layer 310 may be formed of any suitable insulating material, including polymeric materials such as epoxy resins, phenolic resins or silicon containing resins, plastics, composite materials, or combination thereof. In one embodiment, the material of the insulating layer 310 includes epoxy resin with fillers, and the fillers may include silica fillers, aluminum oxide fillers, silicon nitride fillers aluminum nitride fillers, boron nitride fillers or carbon-series fillers, with a ratio of the resin to the fillers ranging from about 1:2 to about 1:30. The formation method of the insulating layer 310 may include molding, coating, dispensing, deposition or combinations thereof, and a curing process may also be applied. In one embodiment, the filler content of the insulating layer 310 is higher than that of the insulating filling material 300. In one embodiment, the insulating layer 310 has a CTE lower than that of the insulating filling material 300. However, it is possible that the CTE differences among the insulating layers 310 and 330 may be small and vary depending on product floorplans or designs.

Referring to FIG. 5, in a subsequent step, a redistribution structure 320 is formed over the reconstructed package substrate board 10WB. In some embodiments, the redistribution structure 320 includes a dielectric layer 322 and metallization patterns 324 embedded in the dielectric layer 322. Referring to FIG. 5, the redistribution structure 320 is formed on and over the planarized insulating layer 310 and on the plurality of conductive pillars 130 and the first semiconductor dies 200. The metallization patterns 324 are electrically and physically connected to the conductive pillar 130. The dielectric layer 322 may be constituted by two or more dielectric sublayers, and the configurations of the metallization patterns 324 may include routing lines, vias, pads or other designs according to routing requirements. In some embodiments, the metallization patterns 324 function as fan-out patterns. In some embodiments, the metallization patterns 324 includes bond pads 324P for bonding or connecting with other components or devices. The dielectric layer 322 may be formed from a material selected from polyimide (PI), benzocyclobutene (BCB), polybenzooxazole (PBO), or any other suitable polymer-based dielectric material including ABF. The metallization patterns 324 be formed from a metal material and/or metal alloys, including copper, aluminum, nickel, titanium, alloys thereof, or combinations thereof, and formed by plating such as an electroplating process. The formation of the dielectric layer 322 may include coating, chemical vapor deposition (CVD), lamination or combinations thereof.

Referring to FIG. 6, after the formation of the redistribution structure 320, second semiconductor dies 250A and third semiconductor dies 250B are mounted onto and bonded to the redistribution structure 320. In some embodiments, the second semiconductor dies 250A and third semiconductor dies 250B are placed with their respective connectors 260A and 260B facing the redistribution structure 320, and the second semiconductor dies 250A and third semiconductor dies 250B are bonded to the redistribution structure 320 through the connectors 260A and 260B. In some embodiments, the second semiconductor dies 250A and third semiconductor dies 250B are electrically connected with the first semiconductor dies 200 through the connectors 260A, 260B and the redistribution structure 320, and are further electrically connected with the package substrate units 10 through the conductive pillars 130 (through insulation vias). In some embodiment, the first semiconductor dies 200 are electrically connected to the second semiconductor dies 250A and third semiconductor dies 250B and function as bridge dies for communicating the second semiconductor dies 250A and third semiconductor dies 250B and interlinking the second semiconductor dies 250A and third semiconductor dies 250B. Alternatively, the first semiconductor die 200 may further enhance or improve the function and performance of either the second semiconductor dies 250A or the third semiconductor dies 250B or both.

In some embodiments, the conductive pillars 130 and the redistribution structure 320 along with the additional semiconductor die(s) 200 may facilitate the delivery of power and transmission of input/output (I/O) signals between the above semiconductor dies 250A and 250B and the package substrate unit(s) 10. Through the arrangement of the constructed interposer 310IS (i.e., the conductive pillars 130 laterally wrapped by the insulating layer 310) and the first semiconductor die(s) 200 located between the package substrate units 10 and the above second semiconductor dies 250A and third semiconductor dies 250B, better performance of the package structure is achieved with less stress and CTE mismatch.

In some embodiments, each one of the second semiconductor dies 250A and third semiconductor dies 250B is or includes a logic die, such as a central processing unit (CPU) die, a graphic processing unit (GPU) die, a micro control unit (MCU) die, an input-output (I/O) die, a baseband (BB) die, or an application processor (AP) die. In an embodiment, at least one of the second semiconductor dies 250A and third semiconductor dies 250B includes a system-on-chip (SoC) die, and at least one of the second semiconductor dies 250A and third semiconductor dies 250B include a memory die such as a high-bandwidth-memory (HBM) die. In some embodiments, the second semiconductor dies 250A and third semiconductor dies 250B may be different types of dies or perform different functions. In other embodiments, the second semiconductor dies 250A and third semiconductor dies 250B may be the same type of dies or perform the same functions. Even though one second semiconductor die 250A and one third semiconductor die 250B are shown in FIG. 6, it is understood that a plurality of second semiconductor dies 250A and a plurality of third semiconductor dies 250B are included, and the number of the dies used in the semiconductor package is not limited by the embodiments herein. In some embodiments, the connectors 260A and 260B of the second semiconductor dies 250A and third semiconductor dies 250B include micro-bumps, copper pillars, stud bumps, or the like.

In some embodiments, the pitch or dimensions and the layouts of the metallization patterns 324 of the redistribution structure 320 are chosen to facilitate routing or redistribution for inter-linking elements of different packaging levels or dies and chiplets/package subunits.

Referring to FIG. 7 and FIG. 8, a singulation process is performed to cut the whole structure shown in FIG. 6 along the cutting lane DL (shown in dotted lines) into individual package structures 18. In some embodiments, the singulation process cuts through the redistribution structure 320, the insulating layer 310 and the insulating filling material 300, without damaging or cutting through the package substrate unit(s) 10, the semiconductor dies or the conductive pillars 130. The singulation process cuts the reconstructed package substrate board 10WB into individual diced or shielded substrates 10SS and the constructed interposer 310IS into intermediary structures 311. In some embodiments, the shielded substrate 10SS is a processed substrate and may be tailored based on product requirements. In some embodiments, the diced substrate 10SS functions as the substrate or circuit substrate for packaging. In some embodiments, the singulation process involves a dicing process with a rotating blade, a sawing process and/or a cutting process using a laser beam, or other suitable processes. After the singulation process, after cutting through the redistribution structure 320, the insulating layer 310 and the insulating filling material 300, the sidewalls of the redistribution structure 320, of the insulating layer 310 and of the insulating filling material 300 are substantially aligned (e.g. vertically aligned). After the singulation process, the carrier C1 is detached along with the removal of the temporary bonding layer 101. Subsequently, after the removal of the carrier C1, the bottommost layer 1103 of the film stack 110B is exposed, openings are formed to reveal the underlying metal wiring layer 1105 and conductive terminals 115 are formed within the openings and on the exposed metal wiring layer 1105. In some embodiments, the conductive terminals 115 include any suitable types of structure capable of forming an electrical connection with a corresponding component, including solder bumps, controlled collapse chip connection (C4) bump, solder balls or the like.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure. Furthermore, the illustrated processes may belong to chips mounted on panel/board processes and may be further fabricated into 3D stacking packages.

Referring to FIG. 8, each individual package structure 18 (each unit) includes the shielded substrate 10SS (including at least one package substrate unit 10 and a portion of the insulating filling material 300 laterally wrapping the package substrate unit 10); the intermediary structure 311 disposed on the shielded substrate 10SS; and at least one first semiconductor die(s) 200 embedded in the intermediary structure 311, located on the shielded substrate 10SS and electrically connected with the package substrate unit 10.

The package substrate unit 10 is shielded by the insulating sheath 300′ (i.e. the insulating filling material 300 laterally wrapping the package substrate unit 10), and the insulating sheath 300′ is in direct contact with and fully covers the whole sidewalls of the package substrate unit 10 in the shielded substrate 10SS. In some embodiments, the substrate 10SS at least includes one or more package substrate unit(s) 10 laterally wrapped by the insulating sheath 300′ (i.e. the insulating filling material 300). The first semiconductor die(s) 200 is located within the span of the package substrate unit 10 and is electrically connected with the package substrate unit 10.

The intermediary structure 311 includes the conductive pillars 130 that are located on the shielded substrate 10SS, located aside the first semiconductor die 200 and directly connected with the package substrate unit 10 and the insulating layer 310 that are located on the shielded substrate 10SS and laterally wrap the first semiconductor die(s) 200 and the conductive pillars 130 (as the encapsulating material layer). The conductive pillars 130 are located aside and spaced apart from the first semiconductor die 200 and surround the first semiconductor die 200, and the conductive pillars 130 are spaced apart from one another and are located within the span of the package substrate unit 10. The insulating layer 310 at least laterally wraps the first semiconductor die(s) 200 and the conductive pillars 130, covering the whole sidewalls of all of the first semiconductor die(s) 200 and the conductive pillars 130.

Also, each individual package structure 18 includes the redistribution structure 320 located on the first semiconductor die(s) 200, on the conductive pillars 130 and located on and extending over the insulating layer 310, and second semiconductor dies 250A and third semiconductor dies 250B located on and connected to the redistribution structure 320. The conductive terminals 115 are located on the bottom side of the package substrate unit 10 and are revealed for further electrical connection.

From the schematic top view of the package structure 18 shown at the right part of FIG. 8, it is seen that the span of the package substrate unit 10 is smaller than the span of the redistribution structure 320 (as well as the span of the insulating filling material 300), the orthogonal projection (span) of each second semiconductor die 250A is partially overlapped with the span of the first semiconductor die 200, and the orthogonal projection (span) of each third semiconductor die 250B is partially overlapped with the span of the first semiconductor die 200. Although not explicitly depicted in the drawing, it is understood that the conductive pillars 130 are arranged beside and surrounding the first semiconductor die 200 but arranged within the span of the package substrate unit 10. It is understood that the package substrate unit 10 including the core layer 100, the TCVs 103 and the film stacks 110A and 110B as described in FIG. 1, and further details are not repeated herein. It is understood that the package substrate unit 10 may be formed with or without the core layer, and may be formed optionally with one or more cavities to accommodate electronic components embedded therein. Exemplary structures will be described later.

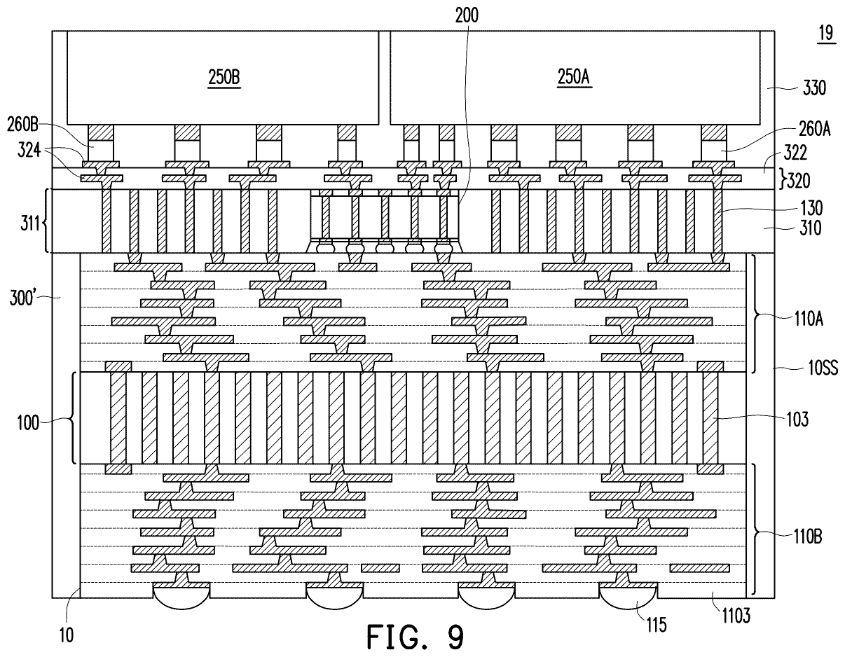

FIG. 9 is a schematic cross-sectional view of an exemplary structure of a package structure in accordance with an embodiment of the present disclosure. The exemplary structure shown in FIG. 9 may be also obtained following the process steps as depicted from FIG. 1 through FIG. 7, following with additional process(es) to be performed. In some embodiments, the process steps and materials used for forming the exemplary structure are similar to the process steps and materials described with reference to FIG. 1-FIG. 7 and in the previous paragraphs, so the detailed descriptions thereof shall be omitted herein. Similar or substantially the same structural parts or elements may be labelled with similar or the same reference numbers as FIG. 1 through FIG. 8, for illustration purposes.

Referring to FIG. 9, the package structure 19 is similar to the package structure 18 as illustrated in the previous paragraphs, but an additional insulating layer 330 is formed over the redistribution structure 320, at least laterally wrapping around the second semiconductor dies 250A and third semiconductor dies 250B, and filling up the gaps between the second semiconductor dies 250A and third semiconductor dies 250B. Such additional insulating layer 330 may be formed before the singulation process, so that the sidewalls of the insulating layers 330 and 310, of the redistribution structure 320 and the insulating filling material 300 are substantially aligned.

In some embodiments, the insulating layer 330 may be formed of any suitable insulating material, including polymeric materials such as epoxy resins, phenolic resins or silicon containing resins, plastics, composite materials, or combination thereof. In one embodiment, the material of the insulating layer 330 includes epoxy resin with fillers, and the fillers may include silica fillers, aluminum oxide fillers, silicon nitride fillers aluminum nitride fillers, boron nitride fillers or carbon-series fillers, with a ratio of the resin to the fillers ranging from about 1:2 to about 1:30. The formation method of the insulating layer 330 may include molding, coating, dispensing, deposition or combinations thereof, and a curing process may also be applied. In one embodiment, the filler content of the insulating layer 330 is higher than that of the insulating filling material 300. In one embodiment, the insulating layer 330 has a CTE lower than that of the insulating layer 310 and lower than that of the insulating filling material 300. However, it is possible that the CTE differences among the insulating layers 300, 310 and 330 may be small and vary depending on product floorplans or designs.

FIG. 10 is a schematic cross-sectional view of an exemplary structure of a package structure in accordance with an embodiment of the present disclosure. The exemplary structure shown in FIG. 10 may be also obtained following the process steps as depicted from FIG. 1 through FIG. 7, with fewer process steps or more additional process(es) to be performed.

Referring to FIG. 10, the package structure 20 is similar to the package structure 18 as illustrated in the previous paragraphs, but additional electronic components 500A and 500B are embedded within the core layer 100 of the package substrate unit(s) 10.

Still referring to FIG. 10, the prefabricated electronic component(s) 500A (only one is shown) is provided, disposed in the cavity of the core layer 100 and embedded in the core layer 100 of the package substrate unit(s) 10. In one embodiment, the electronic component 500A includes integrated passive devices (IPD). For example, the electronic component 500A is electrically connected with the first semiconductor die(s) 200 through the film stack 110A connected to the active surface of the electronic component 500A. In some embodiments, the electronic component(s) 500B (only one is shown) is provided, disposed in the cavity of the core layer 100 and embedded in the core layer 100 of the package substrate unit(s) 10. In one embodiment, the electronic component 500B includes through substrate vias 502 and provides double-sided connectivity and are electrically connected with the conductive terminals 115 and the first semiconductor die(s) 200 through the film stacks 110A and 110B connected to both sides of the electronic component 500B. In one embodiment, the electronic component 500B includes a bridge die. Through the embedded electronic components with double-sided electrical connectivity, the area penalty can be eased or lessened and the impedance of power delivery network can be mitigated.

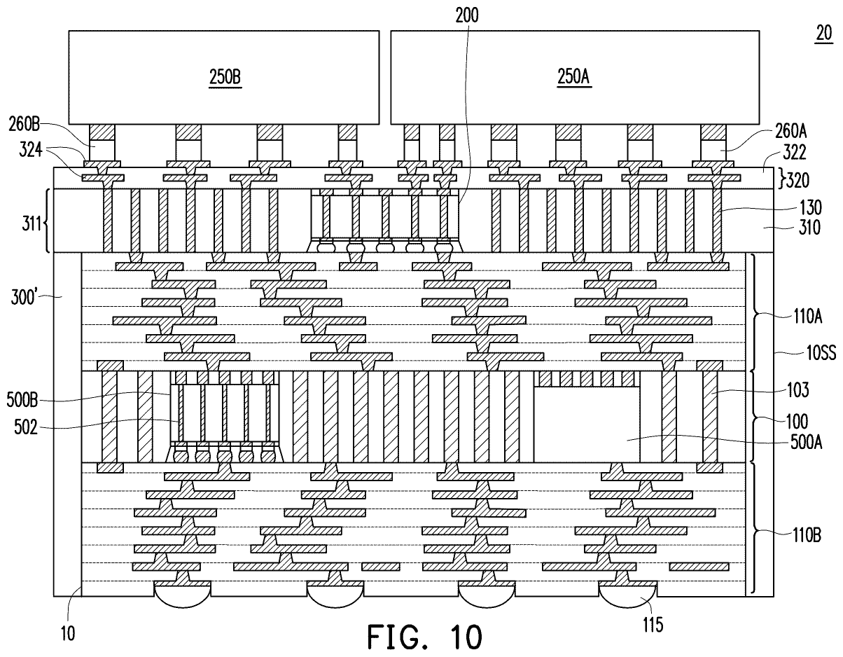

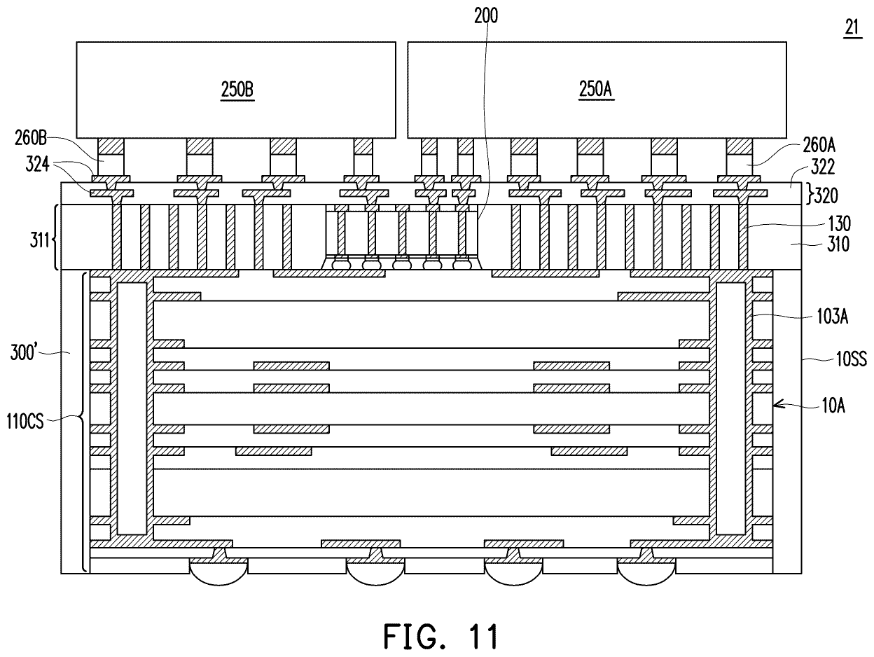

FIG. 11 is a schematic cross-sectional view of an exemplary structure of a package structure in accordance with an embodiment of the present disclosure. The exemplary structure shown in FIG. 11 may be also obtained following the process steps as depicted from FIG. 1 through FIG. 7, with fewer process steps or more additional process(es) to be performed.

Referring to FIG. 11, the package structure 21 is similar to the package structure 18 as illustrated in the previous paragraphs, except for the coreless package substrate unit 10A is included. In some embodiments, the coreless package substrate unit 10A includes a build-up film stack 110CS and plated through hole structures 103A penetrating through the build-up film stack 110CS to provide double-side electrical connection, so that the conductive terminals 115 are electrically connected with the conductive pillars 130 and the above first, second and third semiconductor dies 200, 250A and 250B through the coreless package substrate unit 10A. In an embodiment, the coreless package substrate unit 10A has no core layer 100 and may have a thickness smaller than that of the package substrate unit 10, but the disclosure is not limited thereto.

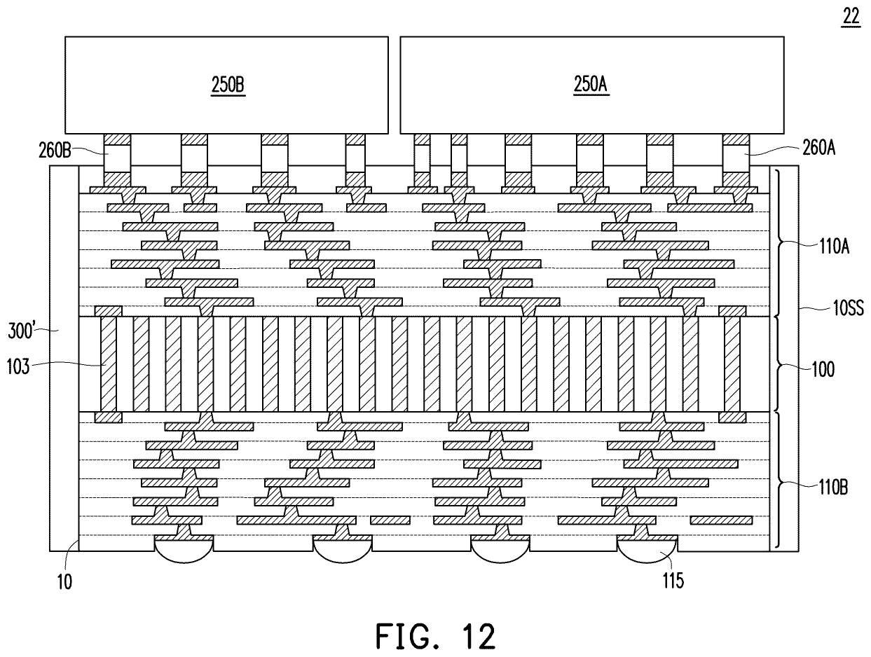

FIG. 12 is a schematic cross-sectional view of an exemplary structure of a package structure in accordance with an embodiment of the present disclosure. The exemplary structure shown in FIG. 12 may be also obtained following the process steps as depicted from FIG. 1 through FIG. 7, with fewer process steps or more additional process(es) to be performed.

Referring to FIG. 12, the package structure 22 is similar to the package structure 18 as illustrated in the previous paragraphs, but the formation of the constructed interposer and the formation of the redistribution structure are omitted. As seen in FIG. 12, the semiconductor dies 250A and 250B are disposed directly on the film stack 110A of the package substrate unit 10 and are directly connected with the topmost metal wiring layer of the film stack 110A through the connectors 260A and 260B, and the conductive terminals 115 are electrically connected with the semiconductor dies 250A and 250B through the package substrate unit 10.

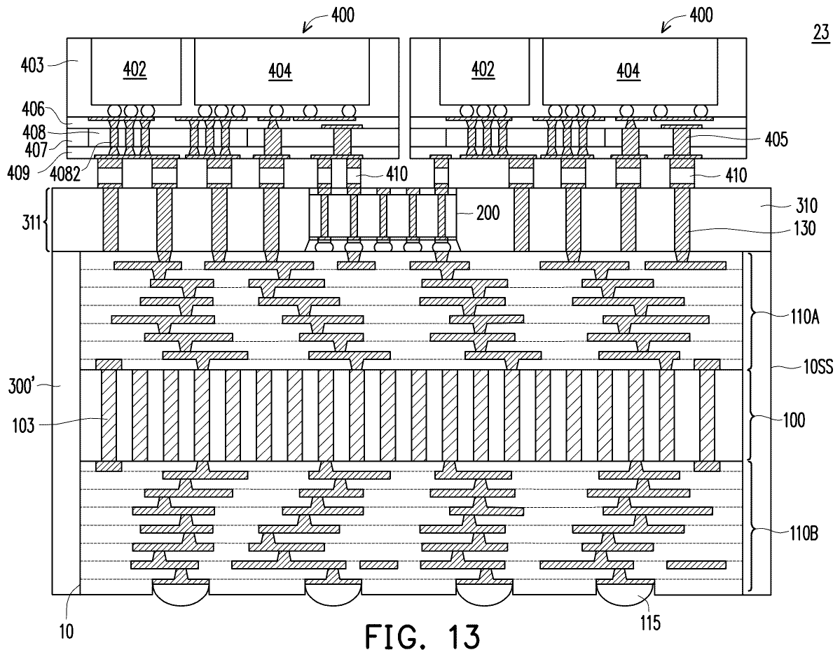

FIG. 13 is a schematic cross-sectional view of an exemplary structure of a package structure in accordance with an embodiment of the present disclosure. The exemplary structure shown in FIG. 13 may be also obtained following the process steps as depicted from FIG. 1 through FIG. 7, with fewer or additional process(es) to be performed. In some embodiments, the process steps and materials used for forming the exemplary structure are similar to the process steps and materials described with reference to FIG. 1-FIG. 7 and in the previous paragraphs, so the detailed descriptions thereof shall be omitted herein. Similar or substantially the same structural parts or elements may be labelled with similar or the same reference numbers as FIG. 1 through FIG. 8, for illustration purposes.

Referring to FIG. 13, the package structure 23 is similar to the package structure 18 as illustrated in the previous paragraphs, but the formation of the redistribution structure 320 is omitted. Also, instead of using the semiconductor dies 250A/250B, package subunits (or chiplets) 400 are mounted on and bonded directly to the conductive pillars 130. In some embodiments, the package subunit 400 includes an integrated fan-out (InFO) package, or a three-dimensional integrated circuit (3DIC) package or a subunit including a photonic module or a power module. In some embodiments as seen in FIG. 13, the package subunit 400 includes a first integrated circuit (IC) 402 and a second IC 404 disposed on a top side of a first redistribution circuit structure 406 and electrically connected to the first redistribution circuit structure 406, an encapsulant 403 laterally wrapping the first and second ICs 402, 404, a third IC 408 located on the other side (the lower side) of the first redistribution circuit structure 406 and an insulative encapsulant 407 laterally wrapping around the third IC 408. The first, second and third ICs 402, 404 and 408 are electrically connected through the first redistribution circuit structure 406. In one embodiment, the third IC 408 includes through substrate vias (TSVs) 4082 and is able to provide double-sided electrical connectivity. In one embodiment, the third IC 408 can facilitate the electrical communication between the first and second ICs 402 and 404. In embodiments, the package subunit 400 includes a second redistribution circuit structure 409 and through insulation vias (TIVs) 405 that are disposed on the second redistribution circuit structure 409, located aside the third IC 408 and extend through the insulative encapsulant 407. The package subunits 400 are electrically connected with the conductive pillars 130 through the connectors 410 located between the second redistribution circuit structure 409 and the conductive pillars 130. The package subunits 400 are electrically connected with the first semiconductor die 200 through the connectors 410 as well, and some or all of the first, second and third ICs 402, 404 and 408 in the package subunits 400 may be electrically connected the first semiconductor die 200. It is understood that semiconductor structures and integrated circuits are included in the package subunits (or chiplets) 400.

In some embodiments, either of the first, second and third ICs 402, 404 and 408 includes one or more semiconductor dies performing different functions, and may independently be or include a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die or an application processor (AP) die, or may independently be or include a memory die such as a high bandwidth memory (HBM) die. In some embodiments, the first IC 402 includes a logic die, the second IC 404 includes a memory die, and the third IC 408 includes an LSI die. In some embodiments, the connectors 410 include micro bumps, copper bumps, controlled collapse chip connection (C4) bump, or the like.

In accordance with some embodiments of the disclosure, a package structure including a substrate, an intermediary structure, a first semiconductor structure and a second semiconductor structure. The substrate includes a package substrate unit and an insulating material covering sidewalls of the package substate unit. The intermediary structure is disposed on the substrate. The intermediary structure includes an encapsulating material and conductive pillars in the encapsulating material, and at least one conductive pillar is electrically connected to the package substrate unit. The first semiconductor structure is disposed on the substrate and embedded in the encapsulating material of the intermediary structure. The second semiconductor structure is disposed over the intermediary structure and electrically connected with the first semiconductor structure through the intermediary structure.

In accordance with some embodiments of the disclosure, a package structure including a substrate, an intermediary structure, a first semiconductor structure, a second semiconductor structure and a third semiconductor structure. The substrate includes a package substrate unit and a first insulating material laterally wrapping the package substate unit. The first insulating material includes a first filler content of first fillers therein. The intermediary structure is disposed on the substrate, and the intermediary structure includes conductive pillars disposed on the package substrate unit and connected with the package substrate unit and a second insulating material laterally wrapping the conductive pillars. The second insulating material includes a second filler content of second fillers therein, and the first filler content is lower than the second filler content. The first semiconductor structure is disposed on the substrate and embedded in the intermediary structure. The second and third semiconductor structures are disposed over the intermediary structure and electrically connected with the first semiconductor structure through the intermediary structure.

In accordance with some alternative embodiments of the disclosure, a method of manufacturing a package structure, includes providing a plurality of package substrate units; forming a reconstructed substrate board by laterally encapsulating the plurality of package substrate units with a first insulating material; forming a constructed interposer on the reconstructed substrate board on the reconstructed substrate board and embedding first semiconductor structures in the constructed interposer; and providing and bonding second semiconductor structures and third semiconductor structures onto the constructed interposer. The second and third semiconductor structures are electrically connected with the first semiconductor structures.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A package structure, comprising:
a substrate, wherein the substrate includes a package substrate unit and an insulating material covering sidewalls of the package substate unit;
an intermediary structure disposed on the substrate, wherein the intermediary structure includes an encapsulating material and conductive pillars in the encapsulating material, wherein at least one conductive pillar of the conductive pillars is electrically connected to the package substrate unit;
a first semiconductor structure, disposed on the substrate and embedded in the encapsulating material; and
a second semiconductor structure, disposed over the intermediary structure and electrically connected with the first semiconductor structure through the intermediary structure.

2. The package structure according to claim 1, wherein a material of the insulating material is different from a material of the encapsulating material.

3. The package structure according to claim 1, further comprising a redistribution structure disposed between the intermediary structure and the second semiconductor structure, wherein sidewalls of the redistribution structure and the intermediary structure are substantially aligned, and the second semiconductor structure disposed on the redistribution structure and the first semiconductor structure are electrically connected through the redistribution structure.

4. The package structure according to claim 3, wherein the first semiconductor structure includes a semiconductor substrate and through semiconductor vias.

5. The package structure according to claim 3, further comprising a third semiconductor structure disposed on the redistribution structure, wherein the first semiconductor structure includes a bridge die and the second and third semiconductor structures are electrically connected through the redistribution structure and the bridge die.

6. The package structure according to claim 5, wherein the third semiconductor structure is located beside the second semiconductor structure and spaced apart from the second semiconductor structure, an orthogonal projection of the second semiconductor structure is partially overlapped with a span of the first semiconductor structure, and an orthogonal projection of the third semiconductor structure is partially overlapped with the span of the first semiconductor structure.

7. The package structure according to claim 3, further comprising an electronic component embedded in the package substrate unit, wherein the electronic component is electrically connected with the first semiconductor structure through the package substrate unit, and is electrically connected with the second semiconductor structure through the package substrate unit, the conductive pillars in the intermediary structure and the redistribution structure.

8. The package structure according to claim 1, wherein the package substrate unit includes a core layer and first and second film stacks disposed respectively on two opposite sides of the core layer.

9. A package structure, comprising:
a substrate, wherein the substrate includes a package substrate unit and a first insulating material laterally wrapping the package substate unit, and the first insulating material includes a first filler content of first fillers therein;
an intermediary structure disposed on the substrate, wherein the intermediary structure includes conductive pillars disposed on the package substrate unit and connected with the package substrate unit, and a second insulating material laterally wrapping the conductive pillars, the second insulating material includes a second filler content of second fillers therein, and the first filler content is lower than the second filler content;
a first semiconductor structure, disposed on the substrate and embedded in the intermediary structure;
a second semiconductor structure, disposed over the intermediary structure and electrically connected with the first semiconductor structure through the intermediary structure; and
a third semiconductor structure, disposed over the intermediary structure and electrically connected with the first semiconductor structure through the intermediary structure.

10. The package structure according to claim 9, wherein the package substrate unit includes a core layer and is a known good substrate unit.

11. The package structure according to claim 9, wherein the package substrate unit is a coreless substrate unit and is a known good substrate unit.

12. The package structure according to claim 9, wherein the package substrate unit includes a glass core layer and through glass vias extending through the glass core layer.

13. The package structure according to claim 9, further comprising a redistribution structure disposed between the intermediary structure and the second semiconductor structure and the third semiconductor structure, and the second and third semiconductor structures disposed on the redistribution structure are electrically connected with each other through the first semiconductor structure and the redistribution structure.

14. The package structure according to claim 13, wherein the first semiconductor structure includes a bridge die, and the bridge die includes:
a semiconductor substrate; and
through substrate vias (TSVs) extending through the semiconductor substrate.

15. The package structure according to claim 12, further comprising an electronic component within the package substrate unit, wherein the electronic component is embedded in the glass core layer and is electrically connected with the first semiconductor structure through the package substrate unit, and is electrically connected with the second and third semiconductor structures through the package substrate unit, the conductive pillars in the intermediary structure and the redistribution structure.

16. The package structure according to claim 9, wherein the package substrate unit includes a solder resist layer disposed on an outermost surface of the package substrate unit and exposed from the first insulating material, and conductive terminals disposed within openings of the solder resist layers.

17. A method of manufacturing a package structure, comprising:
providing a plurality of package substrate units;
forming a reconstructed substrate board by laterally encapsulating the plurality of package substrate units with a first insulating material;
forming a constructed interposer on the reconstructed substrate board on the reconstructed substrate board and embedding first semiconductor structures in the constructed interposer; and
providing and bonding second semiconductor structures and third semiconductor structures onto the constructed interposer, wherein the second and third semiconductor structures are electrically connected with the first semiconductor structures.

18. The method according to claim 17, wherein forming a constructed interposer on the reconstructed substrate board on the reconstructed substrate board and embedding a first semiconductor structure in the constructed interposer comprises:
forming conductive pillars on the plurality of package substrate units;
providing and bonding the first semiconductor structures onto the plurality of package substrate units; and
applying a second insulating material on the reconstructed substrate board to laterally wrapping the first semiconductor structures and the conductive pillars.

19. The method according to claim 17, wherein forming a reconstructed substrate board by laterally encapsulating the plurality of package substrate units with a first insulating material comprises:
arranging the plurality of package substrate units side-by-side and spaced apart from one another with gaps there-between; and
applying the first insulating material over the plurality of package substrate units and filling up the gaps between the plurality of package substrate units to cover sidewalls of the plurality of package substrate units.

20. The method according to claim 17, wherein providing a plurality of package substrate units comprises providing known good package substrate units.
